(19) United States
(12) Patent Application Publication
(10) Pub. No.: US 2016/0141537 A1
(43) Pub. Date: May 19, 2016

(54) NANOSTRUCTURED ANODE-CATHODE ARRAY FOR OPTOELECTRONIC DEVICES

(71) Applicant: KING FAHD UNIVERSITY OF PETROLEUM AND MINERALS, DHAHRAN (SA)

(72) Inventors: KHALIL HARRABI, DHAHRAN (SA); NOUAR TABET, DOHA (QA); IBNELWALEED ALI HUSSEIN, DHAHRAN (SA); MARTYN A. MCLACHLAN, LONDON (GB)

(21) Appl. No.: 14/542,466

(22) Filed: Nov. 14, 2014

(51) Int. Cl. H01L 51/44; H01L 51/52

(52) U.S. Cl. CPC H01L 51/445; H01L 51/5209; H01L 51/5225; H01L 51/5234; H01L 2251/305; H01L 2251/301

(57) ABSTRACT

The nanostructured anode-cathode array for optoelectronic devices is an interdigitated electrode assembly for organic optoelectronic devices. The electrode assembly provides efficiency enhancement in metal oxide (ZnO) and metal (Ag) electrodes for organic optoelectronic devices. The assembly has vertically orientated nanorods in a range of patterns, configurations and volume fractions. The rods have lateral dimensions in the range of 1 nm-500 nm and lengths of 1 nm-10,000 nm. The anode-cathode array can be tuned by altering the dimensions of the individual electrodes and/or modifying the center-to-center distance of anode-anode, cathode-cathode or anode-cathode pairs.

### BACKGROUND OF THE INVENTION

1. Field of the Invention

The present invention relates to optoelectronic devices, and particularly to a nanostructured anode-cathode array for optoelectronic devices that provides charge collection and injection electrodes necessary for optoelectronic semiconductor devices, such as organic photovoltaics (OPVs) and organic light emitting diodes (OLEDs).

2. Description of the Related Art

Organic optoelectronic devices rely on efficient charge collection and injection from their anode and cathode contact terminals. The next generation of organic semiconductor optoelectronic devices, e.g., OPVs and OLEDs, rely on improved charge collection and injection from/into the active layers.

Thus, a nanostructured anode-cathode array for optoelectronic devices solving the aforementioned problems is desired.

### SUMMARY OF THE INVENTION

The nanostructured anode-cathode array for optoelectronic devices is an interdigitated anode-cathode electrode configuration that forms an array that increases efficiency in optoelectronic devices. The array configuration allows improved charge injection in a light emitting device and charge collection in photovoltaic devices. The interdigitated anode-cathode array is arranged as a three-dimensional network of metal-oxide and metal electrodes, which include vertically oriented nanorods disposed in a range of patterns, configurations, and volume fractions. The rod and rod-like structures have lateral dimensions in the range of 1 nm-500 nm and lengths of 1 nm-10,000 nm. Such an anode-cathode array can be tuned by altering the dimensions of the individual electrodes and/or modifying the center-to center distance of anode-anode, cathode-cathode or anode-cathode pairs. Minority carrier injection and collection are balanced, while tunability is enhanced. The array includes vertically extending ZnO nanorods connected to a ZnO base electrode. This ZnO structure serves as an electrode for electron collection. The counterelectrode is made of vertically extending Ag nanorods connected to an Ag base electrode.

These and other features of the present invention will become readily apparent upon further review of the following specification and drawings.

### BRIEF DESCRIPTION OF THE DRAWINGS

FIG. 1 is a diagrammatic perspective view of a nanostructured anode-cathode array for optoelectronic devices according to the present invention.

FIG. 2 is a schematic diagram showing the distribution of charges from the organic semiconductor to adjacent nanorod electrodes in a nanostructured anode-cathode array for optoelectronic devices according to the present invention.

FIG. 3 is a diagrammatic perspective view of a completed circuit incorporating a nanostructured anode-cathode array for optoelectronic devices according to the present invention.

FIG. 4 is a diagram illustrating energy levels in the conductance band of a semiconductor incorporating a nanostructured anode-cathode array for optoelectronic devices according to the present invention.

Similar reference characters denote corresponding features consistently throughout the attached drawings.

### DETAILED DESCRIPTION OF THE PREFERRED EMBODIMENTS

The nanostructured anode-cathode array for optoelectronic devices is an interdigitated anode-cathode electrode configuration that forms an array that increases efficiency in optoelectronic devices. The array configuration allows improved charge injection in a light emitting device and charge collection in photovoltaic devices (e.g., a solar cell). The interdigitated anode-cathode array is arranged as a three-dimensional network of metal-oxide and metal electrodes, which include vertically oriented nanorods disposed in a range of patterns, configurations and volume fractions. Rod and rod like structures having lateral dimensions in the range of 1 nm-500 nm and lengths of 1 nm-10,000 nm are disclosed. Such an anode-cathode array can be tuned by altering the dimensions of the individual electrodes and/or modifying the center-to center distance of anode-anode, cathode-cathode or anode-cathode pairs.

Minority carrier injection and collection are balanced, while tunability is enhanced. The array includes vertically extending ZnO nanorods connected to a ZnO base electrode. This ZnO structure serves as an electrode for electron collection. The counterelectrode is made of vertically extending Ag nanorods connected to an Ag base electrode.

The present nanorod configuration ensures collection of the generated electrons and holes by ZnO and Ag, respectively. The spacing between nanorods can be controlled by using electron beam lithography. The distance between nanorods can be optimized to ensure the best compromise between light absorption and carrier collection. Ag nanowire electrodes have been shown to have a transparency similar to Indium-Titanium-Oxide (ITO). The Ag nanowire electrodes remain the only solution-deposited ITO alternative that meets the performance requirements for photovoltaics, at 10 Ω/Square with 85% transmissivity over the wavelength from 400 to 800 nm. Arrays of vertically aligned, single crystalline silver nanorods can be deposited on silicon substrates via the glancing angle deposition technique using an e-beam system. The single crystalline Ag nanorods are several tens of nanometers in diameter and several hundred nanometers in length. The present anode-cathode array integrates ZnO and Ag nanorod arrays in an interdigitated electrode, so that further enhancement of charge collection is expected, leading to increasing the photocurrent. This has particular relevance to organic solar cells because of the large area between the organic layer and nanorods, compared to the conventional organic solar cell. The interdigitated electrode based on ZnO and Ag nanorod arrays efficiently separate the excitons. The zinc oxide will serve for electron collections, and the silver for hole collections. Moreover, the spacing between the electrodes can be brought down to the diffusion length of the exciton, which can be achieved by using a focused ion beam (F.I.B). Both ZnO and Ag nanorods are combined for collecting photo electrons and holes separately.

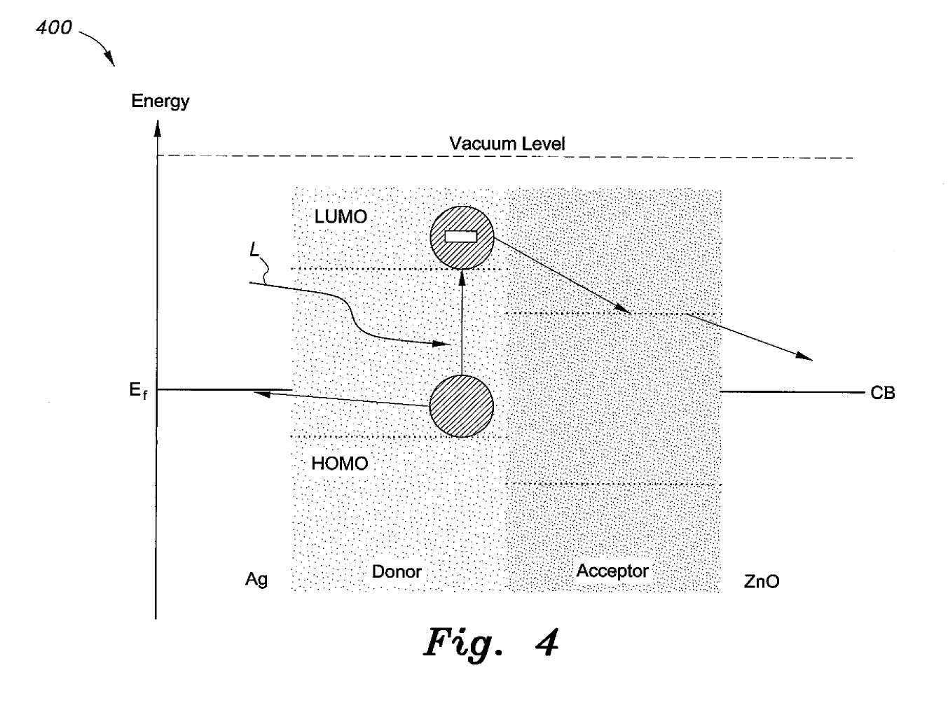

Plot 400 of FIG. 4 is an energy diagram that makes reference to HOMO and LUMO. HOMO and LUMO are acronyms for highest occupied molecular orbital and lowest unoccupied molecular orbital, respectively. The energy difference between the HOMO and LUMO is termed the HOMO-LUMO gap. HOMO and LUMO are sometimes referred to as frontier orbitals. Roughly, the HOMO level is to organic semiconductors what the valence band maximum is to inorganic semiconductors and quantum dots. The same analogy exists between the LUMO level and the conduction band minimum. In organometallic chemistry, the size of the LUMO lobe can help predict where addition to pi ligands will occur. The HOMO and LUMO levels shown in plot 400 assume polymer, ZnO and Ag nanorods with respect to vacuum (Work function of ZnO=3.7 eV and Ag=4.26 eV).

An exciton is a bound state of an electron and hole, which are attracted to each other by the electrostatic Coulomb force. It is an electrically neutral quasiparticle that exists in insulators, semiconductors and in some liquids. The exciton is regarded as an elementary excitation of condensed matter that can transport energy without transporting net electric charge. Excitons may exhibit a kind of bond stability, i.e., binding energy, in nanostructures that require a driving force to dissociate excitons into free carriers. With reference to the diagram 400, the difference between electron affinity levels of the ZnO and Ag nanorod arrays is the driving force required for exciton dissociation in the cell. In the anode-cathode array, the photo-induced electrons are transferred from active polymer material (LUMO) to the acceptor molecule (Low work function), then to the conduction band (CB) of ZnO nanowires. The holes are transferred from the HOMO to the electron acceptor material (High work function).

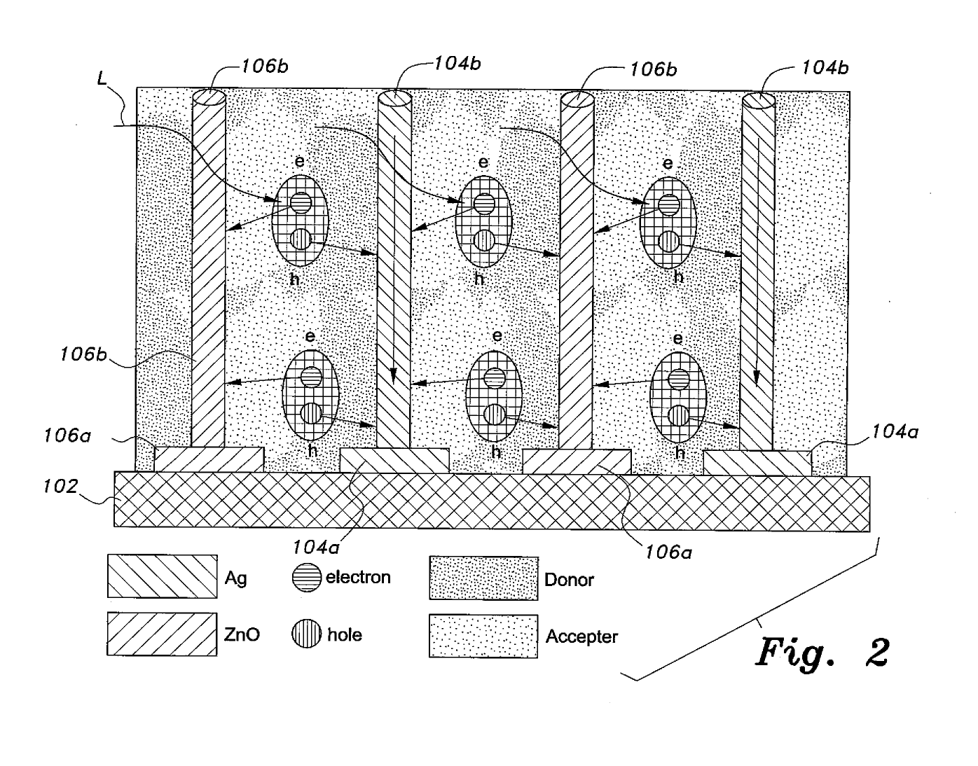

As shown in FIG. 2, the charge transport mechanisms operating in organic solar cells to drive charge carriers towards the electrodes are complicated. Light absorption in organic cells leads directly to the production of electrons and holes in the same material. Since the two carrier types have the same spatial distribution, the concentration gradient, which is the driving force for the transport by diffusion, is identical. Therefore, both charge carriers are driven in the same direction, since this is a small driving force in organic cells. In the present nanostructured anode-cathode array, the electrical potential gradient due to the difference in affinities of the ZnO and Ag is able to separate the photo-induced electrons from the holes effectively. Thus, disassociated negative charge carriers flow towards the zinc oxide nanorods 106b, between alternating Ag 104b and ZnO 106b nanostructures. Similarly, holes flow in the opposite direction via the alternating ZnO 106b and Ag 104a nanostructures. The collection of charge carriers at the electrodes is regularly accomplished by ZnO on one side and Ag contact on the other side.

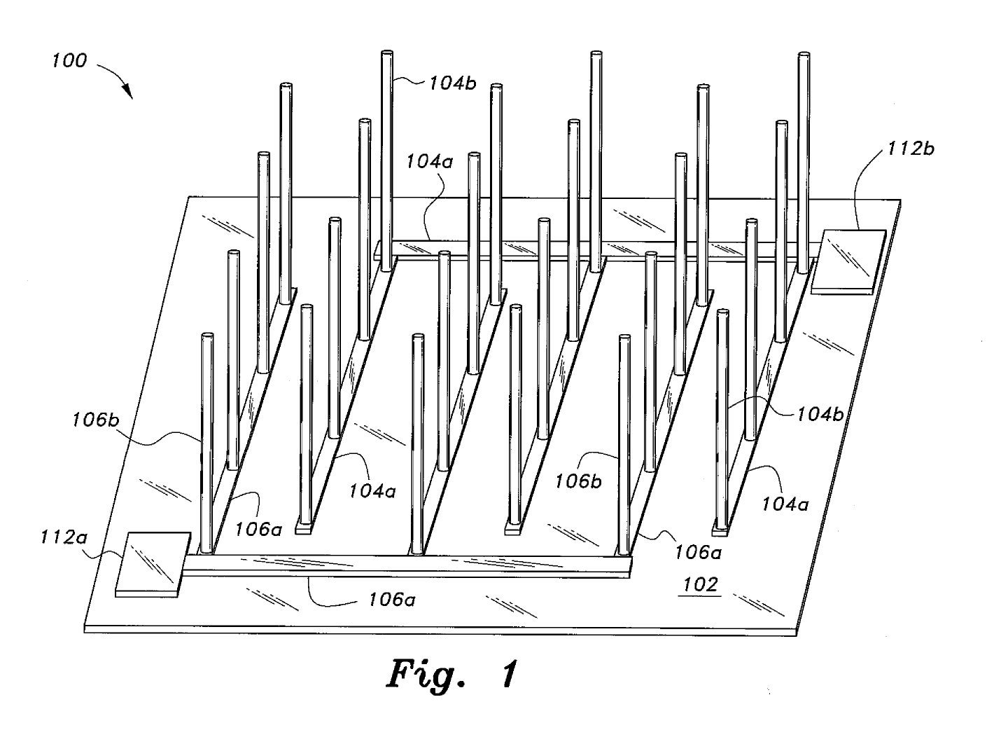

With respect to FIGS. 1, 3, and 4, the nanostructured anode-cathode array 100 is surrounded by organic molecules structured to fulfill the required relative position of the LUMO, HOMO, ZnO and Ag energy levels (shown in FIG. 4) in order to have transfer of the electron and hole between the energy levels when the anode-cathode array 100 is impinged by light L. Note the interdigitation of the 3D nanostructures. An Ag electrode pattern 104a composed of parallel fingers connected to a common bus plate is disposed on a planar substrate 102. As an example, planar substrate 102 may be comprised of silicon. A ZnO electrode pattern 106a, which is also composed of parallel fingers connected to a common bus plate, is disposed on the substrate 102 with the fingers of the zinc oxide pattern 106a in an interdigitated relationship to the fingers of the Ag electrode pattern 104a. A pattern of Ag nanorods 104b extends vertically from the Ag electrode pattern 104a. A pattern of ZnO nanorods 106b extends vertically from the ZnO electrode pattern 106a in an interdigitated relationship to the pattern of Ag nanorods 104b. A ZnO contact pad 112a connected to the bus of the ZnO nanorod supporting pattern 106a terminates the ZnO structures proximate one edge of the substrate 102. An Ag contact pad 112b connected to the bus of the Ag nanorod supporting pattern terminates the Ag structures proximate a diagonally opposite edge of the substrate 102. In the example shown in FIG. 1, the electrodes and extending nanorods respectively form linear comb geometric patterns on the substrate 102 and linear comb geometric patterns perpendicular to the substrate 102, but it should be understood that other geometries may be feasible in the design of the present nanostructured anode-cathode array.

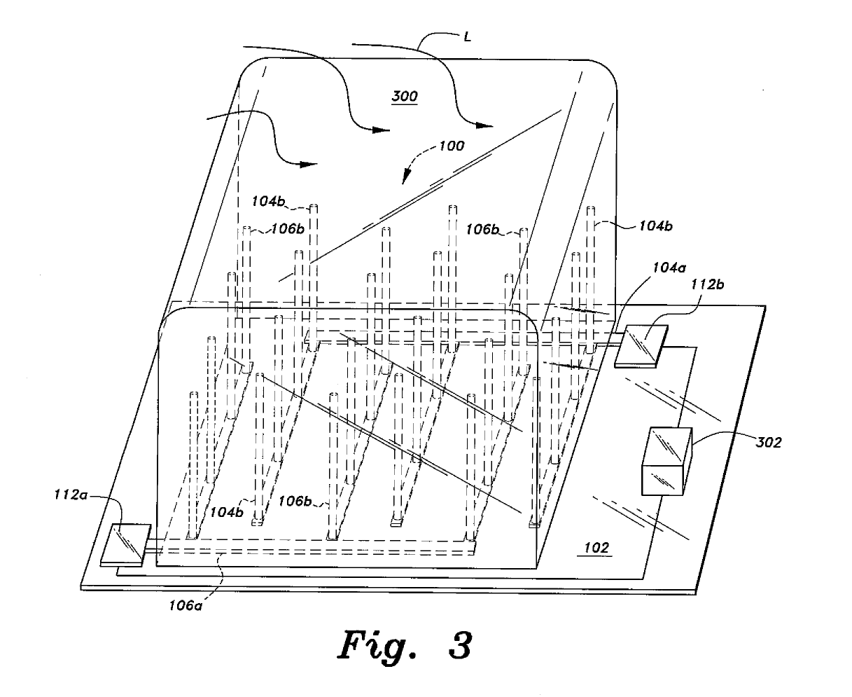

As shown in FIG. 3, the array may be incorporated into a PV cell that includes an optoelectronic housing 300 through which light L can enter to impinge the organic polymer that surrounds the nanorods 104b, 106b. The photovoltaic cell design is an interdigitated electrode filled with organic phase. In FIG. 3, the contact pads 112a and 112b are connected to a load 302. When configured as a light emitting diode, the contact pads 112a, 112b are connected to a voltage source, which provides the energy for electrons and holes to move or conduct in the organic phase between the electrodes such that electrons move from a higher energy level to a lower energy level, accompanied by the emission of light.

It is to be understood that the present invention is not limited to the embodiments described above, but encompasses any and all embodiments within the scope of the following claims.

1. A nanostructured anode-cathode array for organic optoelectronic devices, comprising:
a planar substrate having opposing ends;
a zinc oxide base electrode pattern disposed on the planar substrate;
a silver base electrode pattern disposed on the planar substrate, the silver base electrode pattern being interdigitated with the zinc oxide base electrode pattern such that a plurality of fingers of the silver base electrode pattern alternate with a plurality of fingers of the zinc oxide base electrode pattern;
a pattern of zinc oxide nanostructures connected to and supported by the zinc oxide base electrode pattern and projecting away from a plane of the planar substrate;
a pattern of silver nanostructures connected to and supported by the silver base electrode pattern and projecting away from a plane of the planar substrate; and
wherein the patterns of zinc oxide and silver nanostructures are interdigitated in alternating pairs, the zinc oxide base electrode pattern and the pattern of zinc oxide nanostructures forming a cathode electrode array, the silver base electrode pattern and the pattern of silver nanostructures forming an anode electrode array, the arrays defining an anode-cathode array adapted for use in an organic optoelectronic device.

2. The nanostructured anode-cathode array for optoelectronic devices according to claim 1, wherein the optoelectronic device is an organic photovoltaic device (OPV).

3. The nanostructured anode-cathode array for optoelectronic devices according to claim 1, wherein the optoelectronic device is an organic light emitting diode (OLED).

4. The nanostructured anode-cathode array for optoelectronic devices according to claim 1, wherein the zinc oxide nanostructures comprise nanorods.

5. The nanostructured anode-cathode array for optoelectronic devices according to claim 4, wherein the silver nanostructures comprise nanorods.

6. The nanostructured anode-cathode array for optoelectronic devices according to claim 1, wherein the zinc oxide and silver molecular nanostructure patterns extend perpendicular to the zinc oxide and silver base patterns, respectively.

7. The nanostructured anode-cathode array for optoelectronic devices according to claim 1, wherein the substrate comprises silicon.

8. (canceled)

9. The nanostructured anode-cathode array for optoelectronic devices according to claim 1, further comprising means for tuning the anode array and cathode array.

10. The nanostructured anode-cathode array for optoelectronic devices according to claim 1, further comprising an organic phase filler disposed between the interdigitated electrodes to form a photovoltaic cell.

11. The nanostructured anode-cathode array for optoelectronic devices according to claim 1, wherein the base patterns and the patterns of molecular nanostructures form linear comb geometric patterns on the substrate and linear comb geometric patterns perpendicular to the substrate, respectively.

12. The nanostructured anode-cathode array for optoelectronic devices according to claim 1, further comprising:
a first contact pad connected to the ZnO base proximate one of the ends of the substrate; and
a second contact pad connected to the Ag base pattern proximate the opposing end of the substrate diagonally opposite the first contact pad.

13. A nanostructured anode-cathode array for organic optoelectronic devices, comprising:
a planar substrate having opposing ends;
a first base electrode pattern disposed on the planar substrate;
a second base electrode pattern disposed on the planar substrate, the second base electrode pattern being interdigitated with the first base electrode pattern such that a plurality of fingers of the second base electrode pattern alternate with a plurality of fingers of the first base electrode pattern;
a first pattern of molecular nanostructures connected to and supported by the first base electrode pattern and projecting away from a plane of the planar substrate, the first base electrode pattern and first pattern of molecular nanostructures having an identical molecular composition;
a second pattern of molecular nanostructures connected to and supported by the second base electrode pattern and projecting away from a plane of the planar substrate, the second base electrode pattern and second pattern of molecular nanostructures having a substantially identical molecular composition; and
wherein the first and second patterns of nanostructures are interdigitated in alternating pairs, the first base pattern and the first pattern of molecular nanostructures forming a cathode electrode array, the second base electrode pattern and the second pattern of molecular nanostructures forming an anode electrode array, the arrays defining an anode-cathode array adapted for use in an organic optoelectronic device.

14. The nanostructured anode-cathode array for optoelectronic devices according to claim 13, wherein the optoelectronic device is an organic photovoltaic device (OPV).

15. The nanostructured anode-cathode array for optoelectronic devices according to claim 13, wherein the opto electronic device is an organic light emitting diode (OLED).

16. The nanostructured anode-cathode array for optoelectronic devices according to claim 13, wherein the first pattern molecular nanostructures comprise nanorods.

17. The nanostructured anode-cathode array for optoelectronic devices according to claim 16, wherein the second pattern molecular nanostructures comprise nanorods.

18. The nanostructured anode-cathode array for optoelectronic devices according to claim 13, wherein the first and second molecular nano structure patterns extend perpendicular to the first and second base patterns, respectively.

19. The nanostructured anode-cathode array for optoelectronic devices according to claim 13, wherein the base patterns and the patterns of molecular nano structures form linear comb geometric patterns on the substrate and linear comb geometric patterns perpendicular to the substrate, respectively.

20. The nanostructured anode-cathode array for optoelectronic devices according to claim 13, further comprising:
a first contact pad connected to the first base proximate one of the ends of the substrate; and
a second contact pad connected to the second base pattern proximate the opposing end of the substrate diagonally opposite the first contact pad.
